(19) United States
(12) Patent Application Publication
(10) Pub. No.: US 2012/0272113 A1
(43) Pub. Date: Oct. 25, 2012

(54) ERROR DETECTION AND CORRECTION IN TRANSMITTED DIGITAL SIGNALS

(75) Inventor: Candido Levita, Cambridge (GB)

(73) Assignee: Cambridge Silicon Radio Limited, Cambridge (GB)

(21) Appl. No.: 13/089,901

(22) Filed: Apr. 19, 2011

(51) Int. Cl. H03M 13/05; H04L 1/18; G06F 11/14; G06F 11/10

(52) U.S. Cl. 714/748; 714/776; 714/E11.032; 714/E11.113

(57) ABSTRACT

A wireless communications receiver for receiving data blocks, the receiver comprising: a reception unit arranged to receive a wireless signal, to recover from the wireless signal a data frame containing packets; and an LDPC decoder arranged to recover a data block by LDPC decoding one of the packets. A wireless communications receiver for receiving data blocks, the receiver comprising: a reception unit arranged to receive a wireless signal, to recover a data frame from the wireless signal and to recover an encoded block from the data frame; and an LDPC decoder arranged to recover a data block by LDPC decoding the encoded block. A wireless communications transmitter for transmitting data blocks, the transmitter comprising: an encoder arranged to create an encoded block by LDPC encoding a data block; and a transmit unit arranged to load the encoded block into a data frame as a, or as part of a, packet and transmit the data frame wirelessly.

### FIELD

The invention relates to the field of error detection and error correction in transmitted digital signals.

### BACKGROUND

When a digital signal is transmitted from one place to another, the signal will usually be degraded to some degree by the process of transmitting the data and by the medium it propagates through. As one example, consider the case of a digital signal that is transmitted from a wireless transmitter such as a base station of a mobile telephone network to a wireless receiver such as a mobile telephone. The version of the digital signal that is received by the wireless receiver may be degraded by noise, by interference arising from other signals in the environment, by self interference multipath distortion), by obstacles temporarily blocking the transmission path from the transmitter to the receiver, and so on. As another example, consider the case where the digital signal is a file that is being transmitted from a hard disk to a random access memory (RAM) in a computer by the read head of a hard disk drive. The version of the digital signal that is received by the RAM may be degraded by noise, by contamination or scratches on the hard disk, by physical shock suffered by the hard drive, and so on.

It is therefore conventional to encode a digital signal prior to transmission so that errors in the received version can be detected or corrected or both (sometimes correction can be achieved without explicitly detecting errors). Where such encoding is capable of allowing a degraded, received digital signal to be corrected without a retransmission request then the encoding is often called Forward Error Correction (FEC) encoding.

One popular form of FEC encoding is convolutional encoding. In a convolutional encoding scheme, a digital signal is convolutionally encoded prior to transmission and when the signal is received it is then subjected to probablistic decoding, for example using a Viterbi decoder, in order to recover the digital signal that was transmitted. Since the decoding is probablistic in nature however, it is common practice to add a Cyclic Redundancy Check (CRC) checksum to a digital signal before it is convolutionally encoded and transmitted, so that a receiver can then use the checksum to check whether any errors are contained in the version of the digital signal that is recovered by probablistic decoding. Convolutional encoding and decoding with CRC integrity checking is an approach that is commonly used for radio digital communications and for hard drive access.

FIG. 1 illustrates a transmitter 10 in a radio digital communications network. For example, the transmitter 10 could be a mobile telephone, a base station in a mobile telephone network or a Wifi base station, and so on. As shown, the transmitter 10 comprises a data source 12, a CRC calculator 14, a convolutional encoder 16, a packetiser 18 and a transmit unit 20. It will be apparent to the skilled person that the functional blocks shown in FIG. 1 need not correspond to discrete physical elements within the transmitter 10. Indeed, in a practical embodiment of the transmitter 10, several of the elements shown might be combined into one entity or one or more of the illustrated elements might be implemented a functions performed by a processor.

The data source provides 12 a data signal that is to be transmitted from the transmitter 10. The data signal could be, for example, part of a streamed video signal. The source 12 supplies the digital signal as a series or train of data blocks, an example of which is shown in FIG. 2 and is labelled 22. Each of these data blocks has a length L1.

The data blocks provided by the source 12 are operated on by the CRC calculator 14. When the CRC calculator 14 receives one of the data blocks, the CRC calculator 14 calculates a CRC checksum for the data block and appends the CRC checksum to the data block. FIG. 3 shows the case where the CRC calculator 14 has operated on the data block 22 of FIG. 2. As shown in FIG. 3, a CRC checksum 24 of length L3 is appended to the data block 22, extending the overall length of the data block to L3, where L3=L1+L2.

Once the data blocks produced by the source 12 have been processed by the CRC calculator 14, they are passed to the convolutional encoder 16, where they are convolutionally encoded. FIG. 4 shows an example of a convolutionally encoded block 26 of length L4 that has been produced by the convolutional encoder 16 convolutionally encoding one of the data blocks that has been operated on by the CRC calculator 14.

The convolutionally encoded blocks that are produced by the convolutional encoder 16 are then sent to the packetiser 18. When the packetiser 18 receives a convolutionally encoded block from the convolutional encoder 16, the packetiser 18 divides the convolutionally encoded block into packets for use by the transmitter. Each of the packets has the same length, which in the exemplary system described here is L5. In the case where the length of a convolutionally encoded block that is supplied to the packetiser 18 is not an integer multiple of L5, then the final packet that is created from the convolutionally encoded block is partially empty. FIG. 5 shows the case where the packetiser 18 has divided the convolutionally encoded block 22 into n packets which are labelled 28-1 to 28-n.

The packets that are produced by the packetiser 18 are then supplied to the transmit unit 20. The transmit unit 20 loads the packets into data frames that are then transmitted by a radio modem in the transmit unit 20. In this example, the radio modem uses an orthogonal frequency division multiplexing (OFDM) transmission scheme. Each packet is transmitted as a separate OFDM symbol with the bits making up the packet being modulated onto the subcarriers of the symbol.

FIG. 6 shows a receiver 30 that is designed to receive signals that have been transmitted using a transmitter of the kind shown in FIG. 1. For example, the receiver 30 could be a mobile telephone, a base station in a mobile telephone network or a WiFi base station, and so on The receiver 30 comprises a reception unit 32, an assembler 34, a convolutional decoder 36, a CRC checker 38 and a data sink 40. It will be apparent to the skilled person that the functional blocks shown in FIG. 6 need not correspond to discrete physical elements within the receiver 30. Indeed, in a practical embodiment of the receiver 30, several of the elements shown might be combined into one entity or one or more of the illustrated elements might be implemented a functions performed by a processor.

The reception unit 32 comprises a radio modem that demodulates the OFDM radio signals that reach the receiver 30 and then extracts the data frames, of the kind that are produced by the transmit unit 20. The data frames that are extracted by the radio modem of course contain packets of the kind described in FIG. 5. The reception unit 32 extracts these packets from the data frames that are recovered from the received radio signals and supplies the packets to the assembler 34.

The assembler 34 receives the packets that are extracted by the reception unit 32. The assembler 34 puts the packets together to recover convolutionally encoded blocks of the kind shown in FIG. 4. The assembler 34 sends the recovered convolutionally encoded blocks to the convolutional decoder 36.

When the convolutional decoder 36 receives a recovered convolutionally encoded block from the assembler 34, the convolutional decoder 36 decodes the recovered convolutionally encoded block to recover a data block that should have the format shown in FIG. 3. The convolutionally decoded data blocks that are produced by the convolutional decoder 36 are then sent to the CRC checker 38.

When the CRC checker 38 receives a convolutionally decoded data block from the convolutional decoder 36, the CRC checker 38 checks whether or not the part of that data block that should be a CRC checksum agrees with the part of that data block that should be the data from which the CRC checksum was generated in the originating transmitter. If the checksum and data parts of the block agree, then the data part of the block is considered to be error free and is passed to the data sink 40. However, if the checksum and data parts of the block disagree, then the data part of the block is considered to be in error and the CRC checker 38 requests the retransmission of the frame or frames that contain the packets that make up the data block. (In practice, a CRC check is normally performed on a sequence of bits by dividing the part of the sequence that is supposed to be data plus the part of the sequence that is supposed to be a CRC checksum by the CRC generator polynomial and deeming the sequence to pass the check if the remainder of the division is zero.)

For completeness, it can simply be mentioned that the data sink 40 receives the validated data from the CRC checker 38 and puts that data to its intended purpose. For example, the validated data might represent streamed video, such that the data sink 10 represents a video screen and an audio speaker.

Low-Density Parity-Check (LDPC) codes provide an alternative to convolutional encoding for FEC. LDPC codes are well known. See for example:
“Low-Density Parity-Check Codes”, R G Gallager, Monograph, M.I.T. Press, 1963.

“An Introduction to Low Density Parity Cheek (LDPC) Codes”, Jian Sun, Wireless Communications Research Laboratory, Lane Dept. of Comp Sci. and Elec. Engr., West Virginia University, 3 Jun. 2003.

Traditionally, LDPC encoding has been used for unidirectional, “single-shot” communication in scenarios where as many LPDC decoding iterations as are desired can be performed on a received message in order to correct errors. For example, images captured by space exploration satellites are sometimes LDPC encoded prior to transmission to earth.

### SUMMARY OF THE INVENTION

According to one embodiment, the invention provides a wireless communications receiver for receiving data blocks. This receiver includes a reception unit arranged to receive a wireless signal. This reception unit is also arranged to recover from the wireless signal a data frame containing packets. This receiver also includes an LDPC decoder arranged to recover a data block by LDPC decoding one of the packets.

According to another embodiment, the invention provides a wireless communications receiver for receiving data blocks. This receiver includes a reception unit arranged to receive a wireless signal. This reception unit is arranged to recover a data frame from the wireless signal and to recover an encoded block from the data frame. This receiver also includes an LDPC decoder arranged to recover a data block by LDPC decoding the encoded block.

In one embodiment, the LDPC decoder is configured to apply up to a predetermined number of iterations of LDPC decoding to the encoded block.

In one embodiment, the LDPC decoder is configured to deem reception of the encoded block to have failed if the encoded block has not been successfully LDPC decoded by the end of said predetermined number of iterations.

In one embodiment, the LDPC decoder is configured to request a transmitter to retransmit an encoded block whose reception is deemed to have failed. In one embodiment, the LDPC decoder is configured to format the retransmit request as a request for the retransmission of a frame that included the encoded block whose reception is deemed to have failed.

In one embodiment, the wireless communications receiver is configured to forego an attempt to recover one or more farther data blocks from a group of blocks that contained the encoded block whose reception is deemed to have failed. In one embodiment, the group is the frame that contained the encoded block whose reception is deemed to have failed. In one embodiment, the group is the set of blocks that go to make up a data file. In one embodiment, the wireless communications receiver is configured to power down a part that has become idle through foregoing an attempt to recover one or more further data blocks from the group.

According to one embodiment, the invention provides a wireless communications transmitter for transmitting data blocks. This transmitter includes an encoder arranged to create an encoded block by LDPC encoding a data block. This transmitter includes a transmit unit that is arranged to load the encoded block into a data frame as a—or as part of a—packet and is arranged to transmit the data frame wirelessly.

### BRIEF DESCRIPTION OF THE DRAWINGS

By way of example only, certain embodiments of the invention will now be described by reference to the accompanying drawings, in which:

FIG. 1 is a block diagram schematically illustrating a wireless transmitter that uses convolutional encoding for FEC;

FIG. 2 schematically illustrates a data block;

FIG. 3 schematically illustrates a data block with a CRC checksum;

FIG. 4 schematically illustrates a convolutionally encoded data block;

FIG. 5 schematically illustrates the division of a convolutionally encoded data block into packets;

FIG. 6 is a block diagram schematically illustrating a wireless receiver that uses convolutional decoding for FEC;

FIG. 7 is a block diagram schematically illustrating a wireless transmitter that uses LDPC encoding for FEC;

FIG. 8 is a block diagram schematically illustrating a wireless receiver that uses LDPC: decoding for FEC; and

FIG. 9 is a flow chart describing the operation of the LDPC decoder in the receiver of FIG. 8.

### DETAILED DESCRIPTION

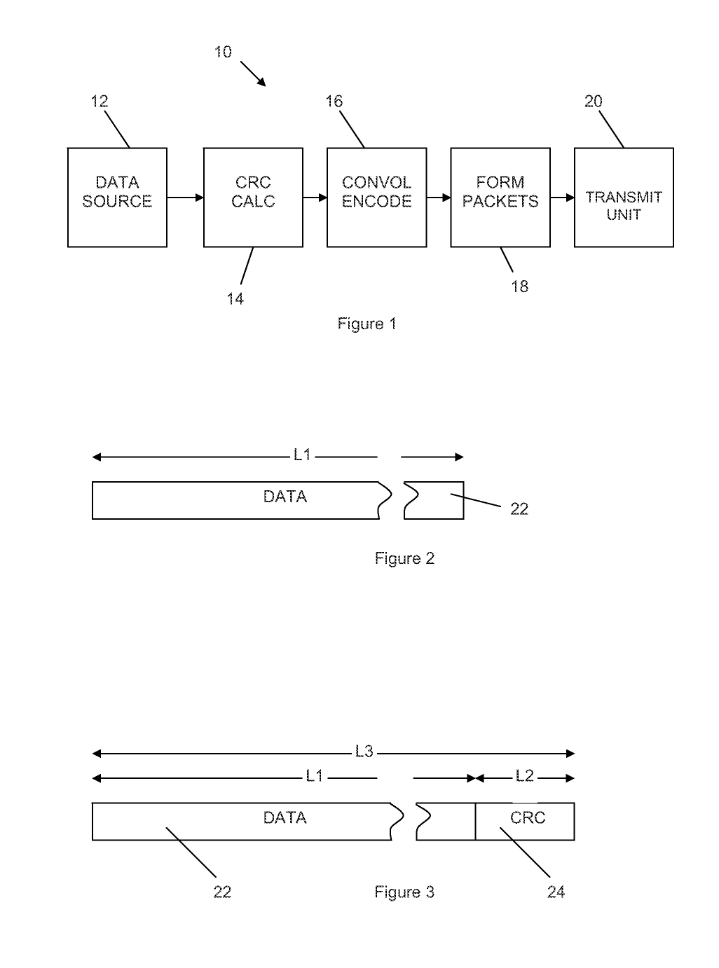

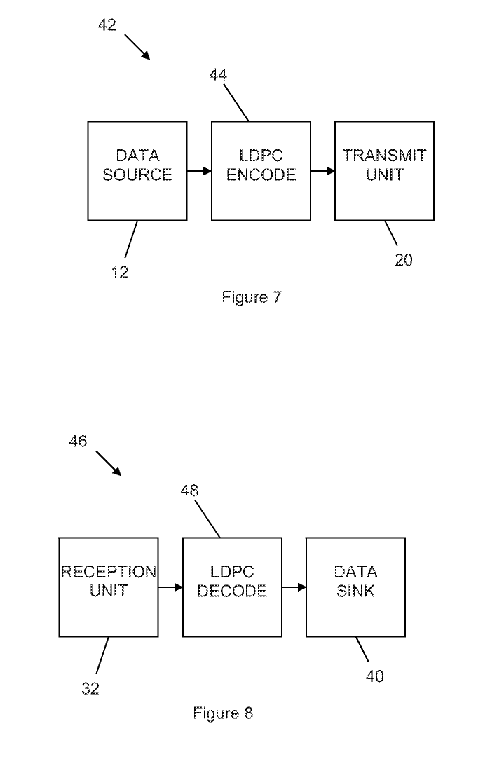

FIG. 7 shows a transmitter 42 in a radio digital communications network. For example, the transmitter 42 could be a mobile telephone, a base station in a mobile telephone network or a WiFi base station, and so on. The transmitter 42 is a variant of the transmitter 10 that is shown in FIG. 1 and elements of FIG. 1 that are reused in FIG. 7 retain the same reference signs and will not be described in detail again.

As shown, the transmitter 42 comprises a data source 12, an LDPC encoder 44 and a transmit unit 20. It will be apparent to the skilled person that the functional blocks shown in FIG. 7 need not correspond to discrete physical elements within the transmitter 42. Indeed, in a practical embodiment of the transmitter 42, several of the elements shown might be combined into one entity or one or more of the illustrated elements might be implemented a functions performed by a processor. In general terms, it can be said that the transmitter 42 is derived from transmitter 10 by replacing the CRC calculator 14, the convolutional encoder 16 and the packetiser 18 with the LDPC encoder 44.

In the transmitter 42, the data source 12 again provides a data signal that is to be transmitted from the transmitter 42 and, again, this digital signal is supplied as a series or train of data blocks, an example of which is shown in FIG. 2 and is labelled 22. Each of these data blocks has a length L1.

When the LDPC encoder 44 receives a data block from the data source 12, the LDPC encoder performs LDPC encoding on the data block in a known manner. The LDPC encoded blocks that are produced by the LDPC encoder 44 are sent to the transmit unit 20.

It will be recalled that the transmit unit 20 is configured to load received packets into data frames and then transmit the data frames using its OFDM radio modem. In transmitter 42, the transmit unit 20 is configured to treat the LDPC encoded blocks from the LDPC encoder 44 as the packets that are loaded into the data frames. It will be recalled that these packets have a length of L5. Therefore, the LDPC encoder 44 is designed, and length L1 selected, so as to ensure that the LDPC encoded blocks produced by the LDPC encoder 44 do not exceed L5 in length. Of course, if an LDPC encoded block produced by the LDPC encoder 44 is less than L5 in length, then that block is simply treated by the transmit unit 20 as a packet that is partially empty. The transmit unit 20 then proceeds to transmit the data frames that have been filled with LDPC encoded blocks that have been treated as packets.

FIG. 8 shows a receiver 46 that is designed to receive signals that have been transmitted using a transmitter of the kind shown in FIG. 7. For example, the receiver 46 could be a mobile telephone, a base station in a mobile telephone network or a WiFi base station, and so on. The receiver 46 is a variant of the receiver 30 that is shown in FIG. 6 and elements of FIG. 6 that are reused in FIG. 8 retain the same reference signs and will not be described in detail again.

As shown in FIG. 8, the receiver 46 comprises a reception unit 32, an LDPC decoder 48 and a data sink 40. It will be apparent to the skilled person that the functional blocks shown in FIG. 8 need not correspond to discrete physical elements within the receiver 46. Indeed, in a practical embodiment of the receiver 46, several of the elements shown might be combined into one entity or one or more of the illustrated elements might be implemented a functions performed by a processor. In general terms, it can be said that the receiver 46 is derived from receiver 30 by replacing the assembler 34, the convolutional decoder 36 and the CRC checker 38 with the LDPC decoder 48.

In receiver 46, the reception unit 32 again employs its OFDM radio modem to extract data frames, of the kind that are produced in a transmitter of the type shown in FIG. 7, from radio signals that reach the receiver 46. On the assumption that the data frames recovered by the reception unit 32 originate from a transmitter of the kind shown in FIG. 7, then each packet in the recovered data frames contains an LDPC encoded data block. The reception unit 20 extracts these LDPC encoded blocks from the data frames and supplies the LDPC encoded blocks to the LDPC decoder 48 for decoding.

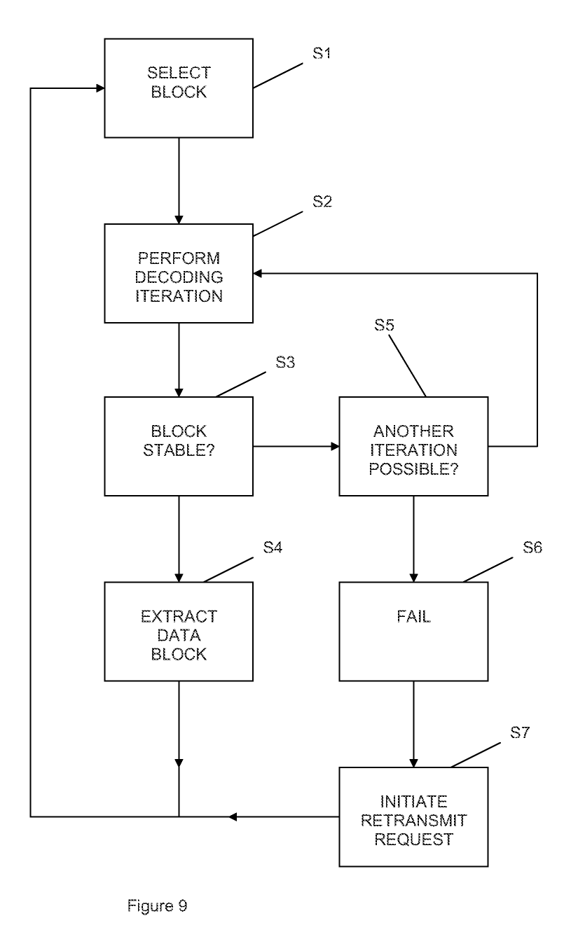

When the LDPC decoder 48 receives an extracted LDPC encoded block from the reception unit 20, the LDPC decoder 48 performs LDPC decoding on the LDPC encoded block. LDPC decoding, as is known to persons skilled in the art and as described in the references cited in the “Background” section of this document, is an iterative process. As is known to persons skilled in the art, successive iterations of LDPC decoding attempt to refine an LDPC encoded block to the point where the LDPC encoded block becomes stable, i.e. to the point where the equations represented by the rows of the parity matrix of the LDPC encoded block are satisfied such that the LDPC block would not change if further LDPC decoding iterations were performed. Once an LDPC encoded block is considered stable, it is assumed to be error free and it is then appropriate to extract, in known fashion, from the refined LDPC encoded block the data block that the originating transmitter encoded to create the LDPC encoded block. The operation of the LDPC decoder will now be briefly summarised with reference to FIG. 9.

FIG. 9 shows a flow chart of the process of attempting to LDPC decode an LDPC encoded data block. The process starts in step S1 in which an LDPC encoded block is selected to undergo an LDPC decoding attempt. In step S2, LDPC decoding iteration is performed on the LDPC encoded block, which at least notionally revises the LDPC encoded data block. In step S3, the at least notionally revised LDPC encoded block that is produced in step S2 is checked to determine whether the LDPC encoded block was actually, as opposed to merely notionally, revised in the decoding iteration of step S2. That is to say, step S3 checks whether the LDPC encoded block has in fact become stable. If no changes are detected in step S3, then the process moves to step S4. In step S4, the LDPC encoded block is deemed, by virtue of having become stable, to be an accurate representation of the LDPC encoded block that was transmitted. In step S4 therefore, the data block that was encoded to create the LDPC encoded block at the transmitter is extracted in known fashion.

However, if changes are detected in step S3, then the process moves to step S5. So that the LDPC decoder can achieve a good data throughput, the LDPC decoder 48 is designed to permit up to a predetermined number of LDPC decoding iterations to be performed on an LDPC encoded block. In step S5 therefore, the process determines whether it is possible to perform another LDPC decoding iteration. If the answer is yes, then the process returns to step S2. If the answer is no, then the process moves to step S6. In step S6, the transmission of the packet corresponding to the LDPC encoded block undergoing decoding is deemed to have failed and the process then moves to step S7.

In step S7, the LDPC decoder 48 initiates a request for the retransmission to receiver 46 of the data frame containing the packet that contained the failed LDPC encoded block. Also in step S7, the LDPC decoder 18 foregoes any attempt to decode LDPC encoded packets of the data frame whose reception has been deemed a failure.

To conclude the description of the receiver 46 then, the data blocks that the LDPC decoder 48 extracts in step S4 are sent to the data sink, where they are put to their end use, for example making an audio-visual presentation to the user of the receiver 46.

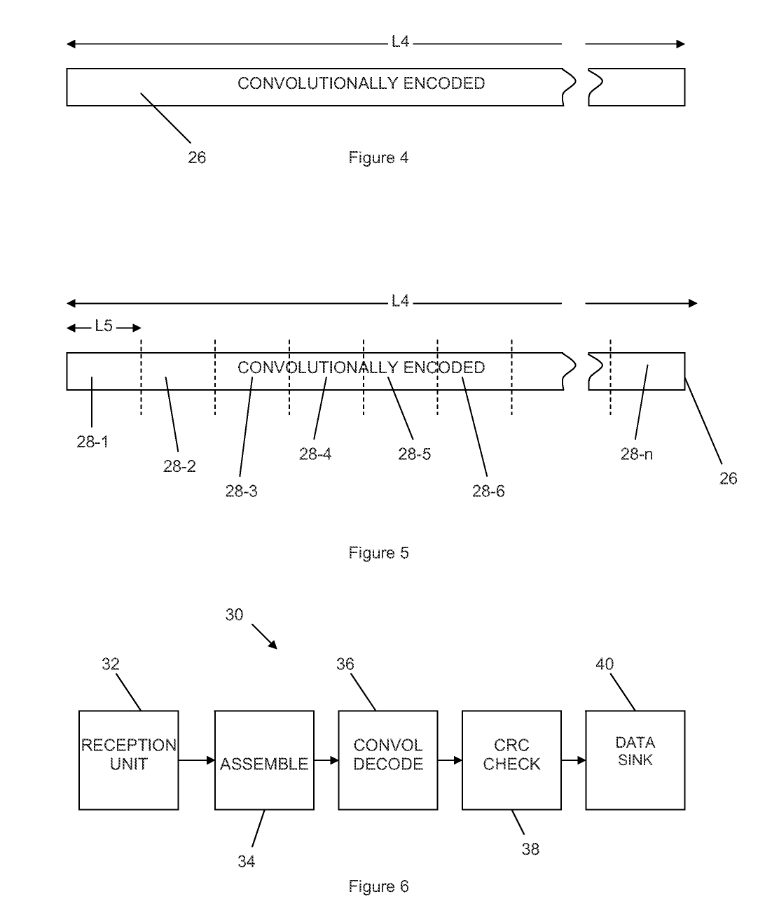

Advantageously, the communication scheme using LDPC FEC outlined with record to FIGS. 7 to 9 can be more efficient than the communication scheme using convolutional encoding FEC described by reference to FIGS. 1 to 6. This is because receiver 46 can request retransmission of a packet corresponding to a LDPC encoded block as soon as that LDPC encoded block is deemed to fail in step S6. In contrast, receiver 30, cannot recognise a failure to receive a convolutionally encoded packet, 28-3, until all of the packets of the convolutionally encoded block, e.g. block 26 in the case of packet 28-3, have been received and the convolutionally encoded block has been reassembled by assembler 34, convolutionally decoded by decoder 36 and checked by CRC checker 38. In other words, receiver 46 experiences a lower latency than receiver 30 when it comes to making retransmission requests. A further advantage lies in the fact that receiver 46, absent any other tasks to perform, can power-down between sending a retransmission request and receiving the requested retransmitted frame. Therefore, its lower latency in the issuing of retransmission requests can be made to translate into an energy saving, such savings being of particular importance when the receiver 46 is battery powered.

1. A wireless communications receiver for receiving data blocks, the receiver comprising: a reception unit arranged to receive a wireless signal, to recover from the wireless signal a data frame containing packets; and an LDPC decoder arranged to recover a data block by LDPC decoding one of the packets.

2. A wireless communications receiver according to claim 1, wherein the LDPC decoder is configured to apply up to a predetermined number of iterations of LDPC decoding to the encoded block.

3. A wireless communications receiver according to claim 2, wherein the LDPC decoder is configured to deem reception of the encoded block to have failed if the encoded block has not been successfully LDPC decoded by the end of said predetermined number of iterations.

4. A wireless communications receiver according to claim 1, wherein the LDPC decoder is configured to request a transmitter to retransmit an encoded block whose reception is deemed to have failed.

5. A wireless communications receiver according to claim 4, wherein the LDPC decoder is configured to format the retransmit request as a request for the retransmission of a frame that included the encoded block whose reception is deemed to have failed.

6. A wireless communications receiver according to claim 4, wherein the wireless communications receiver is configured to forego an attempt to recover one or more further data blocks from a group of blocks that contained the encoded block whose reception is deemed to have failed.

7. A wireless communications receiver according to claim 6, wherein said group is the frame that contained the encoded block whose reception is deemed to have failed.

8. A wireless communications receiver according to claim 6, wherein said group is the set of blocks that go to make up a data file.

9. A wireless communications receiver according to claim 6, wherein the wireless communications receiver is configured to power down a part that has become idle through foregoing an attempt to recover one or more further data blocks from said group.

10. A wireless communications receiver for receiving data blocks, the receiver comprising: a reception unit arranged to receive a wireless signal, to recover a data frame from the wireless signal and to recover an encoded block from the data frame; and an LDPC decoder arranged to recover a data block by LDPC decoding the encoded block.

11. A wireless communications receiver according to claim 10, wherein the LDPC decoder is configured to apply up to a predetermined number of iterations of LDPC decoding to the encoded block.

12. A wireless communications receiver according to claim 11, wherein the LDPC decoder is configured to deem reception of the encoded block to have failed if the encoded block has not been successfully LDPC decoded by the end of said predetermined number of iterations.

13. A wireless communications receiver according to claim 10, wherein the LDPC decoder is configured to request a transmitter to retransmit an encoded block whose reception is deemed to have failed.

14. A wireless communications receiver according to claim 13, wherein the LDPC decoder is configured to format the retransmit request as a request for the retransmission of a frame that included the encoded block whose reception is deemed to have failed.

15. A wireless communications receiver according to claim 13, wherein the wireless communications receiver is configured to forego an attempt to recover one or more further data blocks from a group of blocks that contained the encoded block whose reception is deemed to have failed.

16. A wireless communications receiver according to claim 15, wherein said group is the frame that contained the encoded block whose reception is deemed to have failed.

17. A wireless communications receiver according to claim 15, wherein said group is the set of blocks that go to make up a data file.

18. A wireless communications receiver according to claim 15, wherein the wireless communications receiver is configured to power down a part that has become idle through foregoing an attempt to recover one or more further data blocks from said group.

19. A wireless communications transmitter for transmitting data blocks, the transmitter comprising: an encoder arranged to create an encoded block by LDPC encoding a data block; and a transmit unit arranged to load the encoded block into a data frame as a, or as part of a, packet and transmit the data frame wirelessly.
